(19) United States
(12) Patent Application Publication
(10) Pub. No.: US 2026/0322673 A1
(43) Pub. Date: Oct. 15, 2026

(54) SYSTEM AND METHOD FOR GENERATING WAVEFORMS USING DUTY-CYCLE TIME MODULATION

(71) Applicant: The Hong Kong University of Science and Technology, Hong Kong (CN)

(72) Inventors: Junhui RAO, Hong Kong (CN); Zhaoyang MING, Hong Kong (CN); Jichen ZHANG, Hong Kong (CN); Chi Yuk CHIU, Hong Kong (CN); Ross David MURCH, Hong Kong (CN)

(21) Appl. No.: 19/461,783

(22) Filed: Jan. 28, 2026

Related U.S. Application Data
(60) Provisional application No. 63/761,187, filed on Feb. 21, 2025.
(60) Provisional application No. 63/761,188, filed on Feb. 21, 2025.

(51) Int. Cl. H04L 27/26

(52) U.S. Cl. CPC H04L 27/264

(57) ABSTRACT

A waveform generation apparatus is configured to generate a radio-frequency waveform using duty-cycle-based time modulation. The waveform generation apparatus includes a controller module, a duty-cycle generation module, a pulse-modulation module, and an output interface module. The controller module is configured to provide waveform-defining parameters and timing information associated with a sequence of modulation periods. The duty-cycle generation module is coupled to the controller module and is configured to generate, for each modulation period, a duty-cycle value based on the waveform-defining parameters. The pulse-modulation module is coupled to the duty-cycle generation module and is configured to apply the duty-cycle value to a high-frequency pulse signal to produce a time-modulated waveform. The output interface module is configured to deliver the time-modulated waveform toward a radio-frequency transmission path.

### CROSS-REFERENCE TO RELEVANT APPLICATIONS

The present application claims priority from a U.S. provisional patent application Ser. No. 63/761,187 filed Feb. 21, 2025 and priority from a U.S. provisional patent application Ser. No. 63/761,188 filed Feb. 21, 2025, and the disclosure of which are incorporated by reference in their entirety.

### TECHNICAL FIELD

The present invention relates to wireless communication technology, and more specifically to duty-cycle time-modulated waveform generation for pulse shaping and orthogonal frequency-division multiplexing (OFDM).

### BACKGROUND

Wireless communication systems frequently operate on a symbol-by-symbol basis, where each symbol must be transmitted within a limited time interval. A signal that is temporally confined inherently occupies a broad frequency spectrum, which can lead to interference with adjacent channels. Traditional pulse shaping techniques, including sinc and raised cosine functions, extend the temporal duration of the transmitted signal to confine its spectral occupancy.

These pulse shaping techniques generally rely on temporal overlap between adjacent symbols to maintain throughput. In architectures where overlapping signals are not permitted, such as space shift keying systems in which only one antenna port may radiate at a time, conventional pulse shaping becomes difficult to apply. Using such techniques would require substantially extended symbol durations, resulting in reduced system capacity. Similar challenges arise in in-band full duplex systems that divide each symbol period into transmission and reception intervals, where abrupt switching within the symbol window produces considerable spectrum expansion when conventional signaling is used.

Orthogonal frequency division multiplexing has also been widely adopted to handle channel impairments by distributing information across multiple orthogonal subcarriers. OFDM requires that a communication system be capable of synthesizing and transmitting multiple subcarrier signals simultaneously. This requirement is incompatible with systems that prohibit time-domain signal overlap, including space shift keying architectures that operate with a single radio frequency (RF) chain. In addition, conventional OFDM produces a high peak-to-average power ratio, which affects power amplifier efficiency and can degrade receiver performance due to out-of-band emissions and in-band distortion.

These characteristics illustrate persistent limitations in wireless communication systems that operate under strict temporal constraints or rely on switch-based signal paths. Approaches that depend on symbol overlap, extended symbol durations, or simultaneous multicarrier synthesis encounter fundamental restrictions in such environments. The limitations of these conventional techniques motivate continued investigation into signaling strategies that remain compatible with these structural and timing constraints.

Accordingly, there is a need for a signaling approach that supports waveform generation under strict temporal constraints while maintaining spectral compactness.

### SUMMARY OF INVENTION

It is an objective of the present invention to provide systems and methods to address the aforementioned shortcomings and unmet needs in the state of the art.

In the present invention, systems and methods are provided for generating radio-frequency waveforms using duty-cycle-based time modulation under architectures that restrict simultaneous or overlapping transmissions. The invention introduces two complementary signaling approaches that apply the same underlying principle of duty-cycle control to enable waveform generation compatible with strict temporal constraints. One approach adapts duty-cycle time modulation for pulse shaping, and the other adapts it for multicarrier waveform synthesis in orthogonal frequency division multiplexing.

In one implementation, waveform generation is achieved through a duty-cycle-based approach tailored for pulse-shaped signaling. To mitigate spectrum expansion and avoid longer symbol durations, duty-cycle-modulated pulse shaping is proposed in the present disclosure. When a periodic pulse signal is employed to modulate a signal, the magnitude of the fundamental harmonic is directly proportional to the duty cycle of the pulse signal. The central idea of the proposed duty-cycle-modulated pulse shaping technique is to utilize a pulse signal with a continuously changing duty cycle to implement the required waveform of pulse shaping in all the desired simultaneously. If the modulation period of the pulse signal is much shorter than the duration of the original signal, this approach can replicate the performance of traditional pulse shaping.

In another implementation, the duty-cycle-based time modulation framework is applied to the synthesis of multicarrier waveforms for orthogonal frequency division multiplexing. To implement OFDM in systems with such constraints and mitigate the high peak-to-average power ratio (PAPR), duty-cycle-modulated OFDM is proposed in the present disclosure. When a periodic pulse signal modulates a carrier signal, the magnitude of the fundamental harmonic is directly proportional to the pulse signal's duty cycle. The central concept of the proposed duty-cycle-modulated OFDM technique is to use a pulse signal with a continuously varying duty cycle to generate the required OFDM waveform across all ports simultaneously. If the modulation period of the pulse signal is significantly shorter than the duration of the original signal, this approach can replicate the performance of traditional OFDM. Furthermore, since the proposed OFDM is not realized by modulating the envelope, the peak to average power ratio is maintained at an acceptable level.

In accordance with a first aspect of the present invention, a waveform generation apparatus is provided. The waveform generation apparatus is configured to generate a radio-frequency waveform using duty-cycle-based time modulation. The waveform generation apparatus includes a controller module, a duty-cycle generation module, a pulse-modulation module, and an output interface module. The controller module is configured to provide waveform-defining parameters and timing information associated with a sequence of modulation periods. The duty-cycle generation module is coupled to the controller module and is configured to generate, for each modulation period, a duty-cycle value based on the waveform-defining parameters. The pulse-modulation module is coupled to the duty-cycle generation module and is configured to apply the duty-cycle value to a high-frequency pulse signal to produce a time-modulated waveform. The output interface module is configured to deliver the time-modulated waveform toward a radio-frequency transmission path.

In accordance with a second aspect of the present invention, a method for generating a radio-frequency waveform using duty-cycle-based time modulation is provided. The method includes steps as follows: receiving waveform-defining parameters and timing information for a sequence of modulation periods; generating, for each modulation period, a duty-cycle value based on the waveform-defining parameters; applying the duty-cycle value to a pulse signal having a modulation frequency higher than a symbol rate of the radio-frequency waveform to produce a time-modulated waveform, wherein a fundamental harmonic of the time-modulated waveform corresponds to the waveform-defining parameters; and outputting the time-modulated waveform toward a radio-frequency transmission path.

Together, these techniques provide a unified framework for waveform generation in wireless communication systems operating under strict temporal and hardware constraints. By applying duty-cycle-based time modulation to reproduce the effects of conventional modulation functions, the present invention addresses persistent challenges such as spectrum expansion, high peak to average power ratio, and incompatibility with architectures that prohibit overlapping time-domain signals. This approach enables the realization of advanced signaling capabilities while maintaining performance characteristics comparable to traditional methods.

### BRIEF DESCRIPTION OF DRAWINGS

Embodiments of the invention are described in more details hereinafter with reference to the drawings, in which:

FIG. 1A, FIG. 1B, FIG. 1C, and FIG. 1D illustrate the characteristics of a representative radio-frequency signal when transmitted within a limited symbol interval;

FIG. 2 shows basic schematic of the time-modulated signal according to some embodiments of the present invention;

FIG. 3 provides example of the proposed duty-cycle-modulated pulse shaping;

FIG. 4 shows a basic SSK transmitter with two isolated ports according to some embodiments of the present invention;

FIG. 5 shows signals without pulse shaping for transmitting the bit sequence “0 1 1 0 1 0”;

FIG. 6 shows signals with traditional raised cosine pulse shaping (α=0.8 and k=3) for transmitting the bit sequence “0 1 1 0 1 0”;

FIG. 7 shows duty cycle of the duty-cycle-modulated pulse shaping;

FIG. 8 shows signal with raised cosine (α=0.8 and k=3) duty-cycle-modulated pulse shaping for transmitting the bit sequence “0 1 1 0 1 0,”;

FIG. 9 shows a time-modulated in-band full-duplex (IBFD) system according to some embodiments of the present invention;

FIG. 10 shows time division of transmission and reception in symbol rate;

FIG. 11 shows an IBFD system with the proposed duty-cycle-modulated pulse shaping technique;

FIG. 12 illustrates a generalized waveform generation system configured to implement duty-cycle-based time modulation according to some embodiments of the present invention;

FIG. 13 illustrates an SSK extension system configured to operate in conjunction with the waveform generation system of FIG. 12 according to some embodiments of the present invention;

FIG. 14 illustrates an IBFD extension system configured to operate in conjunction with the waveform generation system of FIG. 12 according to some embodiments of the present invention;

FIG. 15 shows a duty cycle and signals for transmitting the bit sequence “0 1 1 0 1 0” across six subchannels;

FIG. 16 shows the duty-cycle behavior and corresponding spectral characteristics for the duty-cycle-modulated OFDM example;

FIG. 17 shows duty-cycle characteristics for the duty-cycle-modulated OFDM example; and

FIG. 18 illustrates a duty-cycle-modulated OFDM waveform generation system configured to synthesize a multicarrier waveform using a time-varying duty-cycle sequence according to some embodiments of the present invention.

### DETAILED DESCRIPTION OF THE INVENTION

In the following description, systems and methods for generating waveforms using duty-cycle time modulation and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

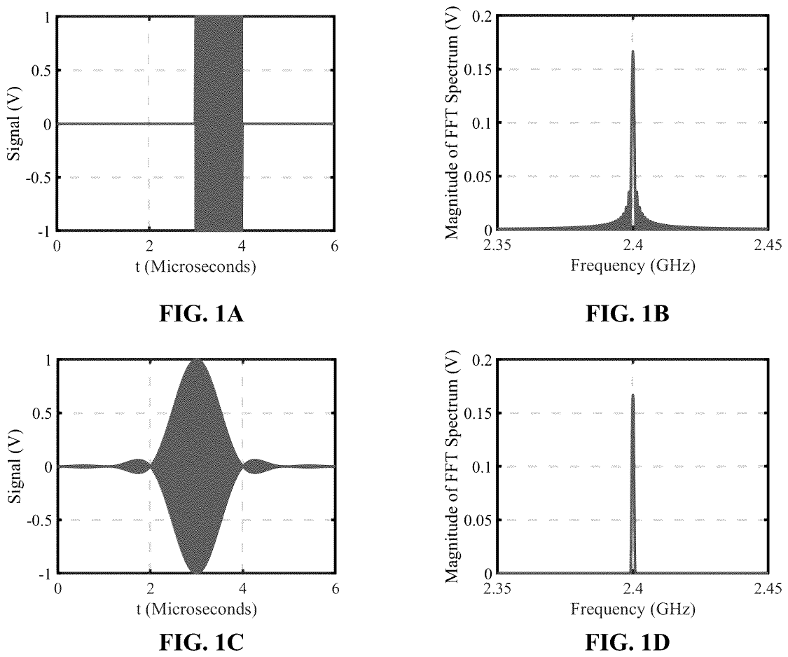

FIG. 1A, FIG. 1B, FIG. 1C, and FIG. 1D illustrate the characteristics of a representative radio-frequency signal when transmitted within a limited symbol interval. In this example, a 2.4 GHz sinusoidal waveform is confined to a single symbol duration, resulting in a time-limited signal as shown in FIG. 1A. The corresponding spectrum in FIG. 1B exhibits significant bandwidth expansion due to the abrupt truncation of the waveform in the time domain. When a raised cosine envelope is applied, as shown in FIG. 1C, the temporal support of the signal becomes extended and the associated spectrum in FIG. 1D becomes more compact. These illustrations demonstrate the conventional function of pulse shaping techniques, which suppress spectral widening by extending or smoothing the transmitted waveform.

Although traditional pulse shaping can effectively reduce spectral expansion, it commonly requires temporal overlap between adjacent symbols or an extended transmission interval, which may be incompatible with communication architectures that prohibit overlapping time-domain signals or that operate under strict symbol timing constraints. In view of these limitations, the present invention introduces signaling methods that generate the desired waveform characteristics through duty-cycle-based time modulation rather than envelope shaping. The following descriptions provide the underlying theory of the time-modulated signal.

### Basic Theory of the Time-Modulated Signal

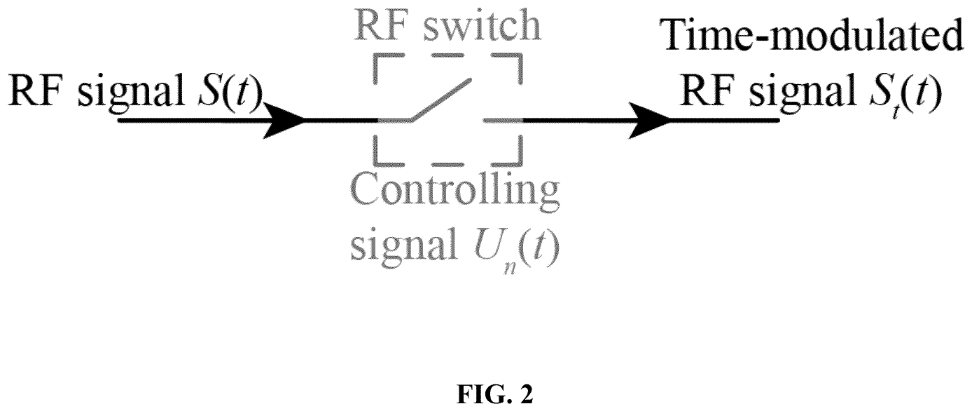

FIG. 2 shows basic schematic of the time-modulated signal according to some embodiments of the present invention. The illustration of FIG. 2 is set for outlining the fundamental theory of the time-modulated technique. Consider an RF signal, S(t). By applying time-modulated signals Uₙ(t) to periodically control the ON/OFF state of an RF switch, a time-modulated signal Sₜ(t)=S(t) Uₙ(t) is produced at the output of the RF switch. The RF switch operates in two states: ON or OFF. This operation can be described by a periodic pulse function with a modulation period Tp, defined as:

$${U}_{n} ( t ) = \{ \begin{matrix}1 , & ( n - 1 ) {T}_{p} < t < ( n - 1 ) {T}_{p} + τ \\ 0 , & otherwise\end{matrix} \qquad ( 1 )$$

where τ/Tₚ is the duty cycle of Uₙ(t). By applying the Fourier transform, Uₙ(t) can be expressed as:

$${U}_{n} ( t ) = {\sum }_{m = - ∞}^{+ ∞} {a}_{m} \cdot {e}^{j 2 π m \cdot {f}_{p} \cdot t} , m ∈ Z \qquad ( 2 )$$

where fₚ=1/Tₚ is the time modulation frequency, and aₘ represents the equivalent complex excitation in the m-th harmonic. The value of aₘ is determined by:

$${a}_{m} = \frac{1}{{T}_{p}} {\int }_{0}^{{T}_{p}} {U}_{n} ( t ) {e}^{- j 2 π m \cdot {f}_{p} t} dt \qquad ( 3 )$$

Thus, aₘ depends on both the duty cycle and the time delay of Uₙ(t). For the proposed pulse shaping, the focus is on the fundamental harmonic, a₀, while other time-modulated harmonics can be filtered out. From equation (3), it follows that:

a₀=τ/Tₚ (4)

This indicates that by adjusting the duty cycle of the controlling signal, we can modulate the magnitude of the fundamental harmonic of the time-modulated signal Sₜ(t) as we desired.

Based on the foregoing theoretical framework, the present invention applies duty-cycle time modulation to two distinct categories of waveform generation. The first approach, referred to as a “Duty-Cycle Time-Modulated Pulse Shaping Scheme,” adapts the duty-cycle control mechanism to produce pulse-shaped envelopes suitable for systems that cannot accommodate overlapping symbol intervals. The second approach, referred to as a “Duty-Cycle Time-Modulated Multicarrier Waveform Scheme,” extends the same modulation principle to the synthesis of multicarrier waveforms such as those used in orthogonal frequency division multiplexing. The following sections describe these two schemes in detail.

### The First Approach: Duty-Cycle Time-Modulated Pulse Shaping Scheme

As demonstrated in equation (4), when a periodic pulse signal is used to modulate a signal, the magnitude of the fundamental harmonic is linearly related to the duty cycle of the pulse signal. The key concept of the proposed duty-cycle-modulated pulse shaping is to use a pulse signal with a continuously varying duty cycle to modulate the signal to mimic the traditional pulse shaping function, such as raised cosine function. When the period of the pulse signal, “modulation period,” is significantly shorter than the duration of the original signal, this method can achieve performance similar to traditional pulse shaping. An additional advantage of using a high-frequency pulse signal is that the harmonics introduced by modulation are far away from the signal of interest, making it easier to filter out these undesired spectral components.

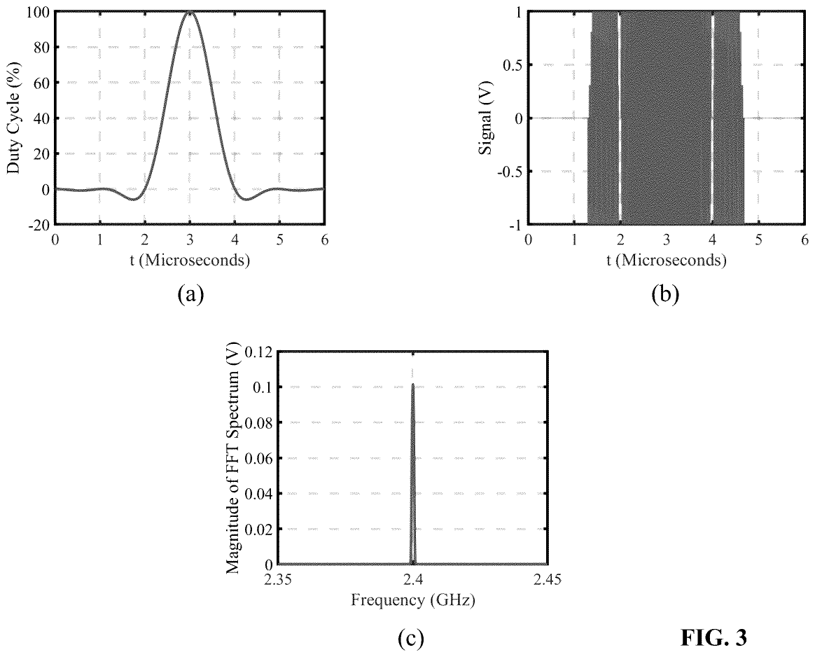

FIG. 3 provides example of the proposed duty-cycle-modulated pulse shaping, containing: part(a) Duty cycle of the pulse signal; part(b) Signal with duty-cycle-modulated pulse shaping; and part(c) Spectrum of the signal with duty-cycle-modulated pulse shaping.

As shown in FIG. 3, the original signal is a 2.4 GHz sine wave, as depicted in FIG. 1A, with a duration of 1 μs from (t=3) μs to (t=4) μs. Instead of applying traditional pulse shaping by modulating its envelope, a high-frequency pulse signal is utilized with a modulation period of 10 ns. Consequently, for the 1 μs duration of the signal, there are a total of 100 modulation periods, and 600 modulation periods when the original signal is extended to 6 μs based on the raised cosine function (α=0.8 and k=3). For each modulation period, a different duty cycle is assigned, as shown in part(a) of FIG. 3. The corresponding time-domain signal is shown in part(b) of FIG. 3, where it can be observed that while the duty cycle changes over time, the magnitude remains constant. Similar to traditional pulse shaping, the proposed method effectively confines the signal's spectrum within a very limited bandwidth, as illustrated in part(c) of FIG. 3. The proposed pulse shaping method has numerous promising applications, two of which are discussed in the following sections.

### The First Approach-Application Example I: SSK Transmitter

One application of the proposed technique is for pulse shaping in SSK transmitters, without extending symbol duration or reducing the transmission symbol rate.

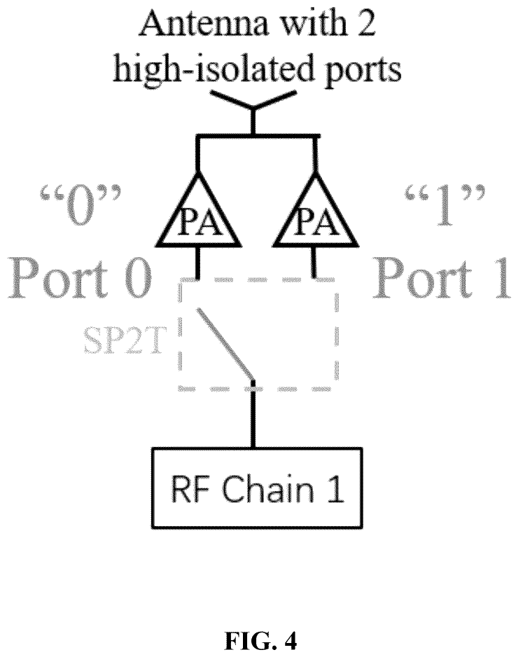

FIG. 4 shows a basic SSK transmitter with two isolated ports according to some embodiments of the present invention. Transmitting carrier signals through port 0 represents the transmission of bit “0,” while transmitting carrier signals through port 1 represents the transmission of bit “1.” The power amplifier is configured after the modulation so that the power loss due to the modulation harmonics and idle can be negligible.

To illustrate this, consider a basic SSK transmitter as depicted in FIG. 4, featuring a single RF chain and an antenna with two isolated ports. Symbol selection is achieved by choosing which port radiates the carrier signal, with each symbol representing one bit of data. Selecting port 1 corresponds to transmitting bit “1” and vice versa. It should also be noted that the power amplifier is configured after the modulation so that the power loss due to the modulation harmonics and idle can be negligible. The overall power efficiency with the proposed technique will remain almost the same.

Assume the carrier signal frequency is 2.4 GHz, the symbol duration is 1 s, and the modulation frequency of the duty-cycle-modulated pulse signal is 100 MHz corresponding to 10 ns modulation period. In the following analysis, it is considered that transmitting the bit sequence “0 1 1 0 1 0” as an example.

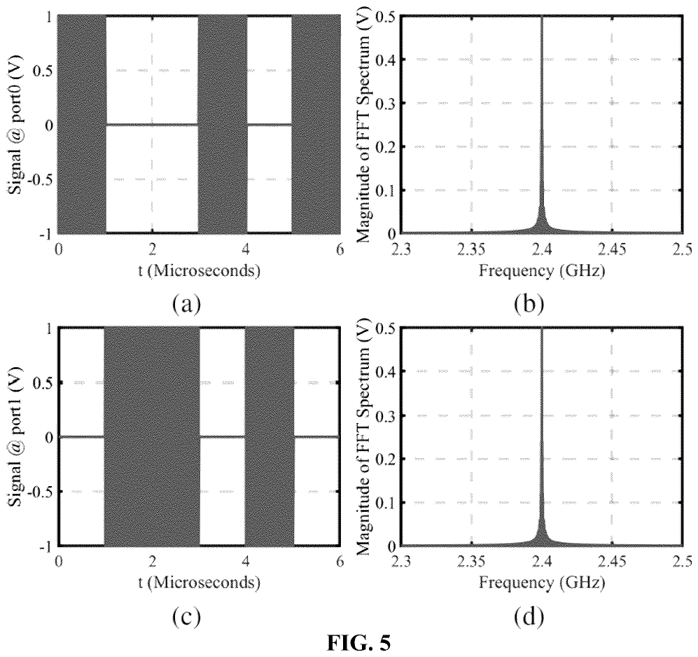

Initially, the signals transmitted without any pulse shaping technology are shown in FIG. 5. FIG. 5 shows signals without pulse shaping for transmitting the bit sequence “0 1 1 0 1 0,” containing: part(a) Signals at port 0; part(b) Spectrum of signals at port 0; part(c) Signals at port 1; and part(d) Spectrum of signals at port 1. It is evident that port 0 transmits signals during the 1st, 4th, and 6th symbol times, while port 1 transmits during the 2nd, 3rd, and 5th symbol durations, corresponding to the data 0 1 1 0 1 0.” However, as seen in part(b) and part(d) of FIG. 5, due to the limited symbol duration, there is spectrum expansion in the transmitted signals. This expansion into adjacent frequency channels is undesirable in transmitter design, as it can cause interference.

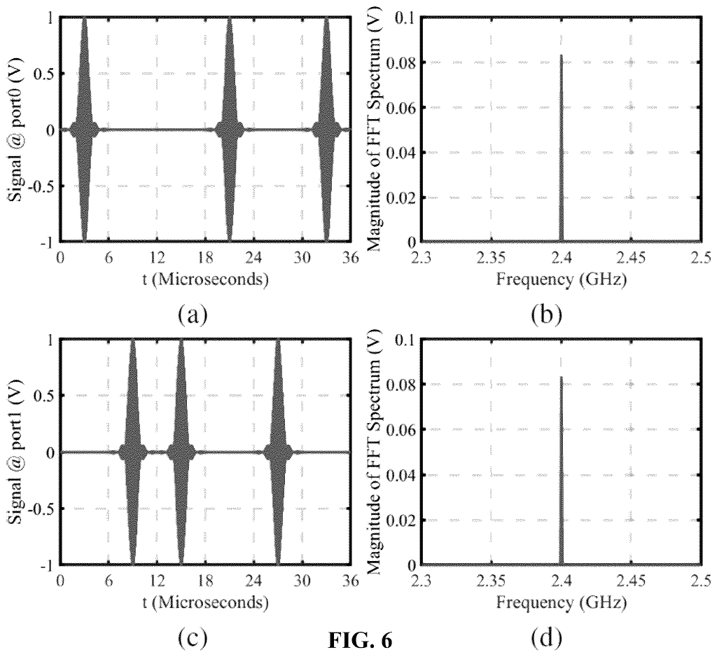

To address spectrum expansion, traditional raised cosine pulse shaping (α=0.8 and k=3) can be employed, as shown in FIG. 6. FIG. 6 shows signals with traditional raised cosine pulse shaping (α=0.8 and k=3) for transmitting the bit sequence “0 1 1 0 1 0,” containing: part(a) Signals at port 0; part(b) Spectrum of signals at port 0; part(c) Signals at port 1; and part(d) Spectrum of signals at port 1. With raised cosine pulse shaping, the duration of each transmitted symbol is extended to six times the original symbol duration for k=3. This requires six times longer to transmit a single symbol. Furthermore, when the RF chain is connected to one antenna port, other symbols (from the other antenna port) cannot be transmitted simultaneously. Therefore, in a single RF-chain SSK system, overlapping pulse-shaped signals in time domain cannot be realized, reducing capacity or throughput by six times. However, as shown in part(c) and part(d) of FIG. 6, the pulse shaping technique results in a clear spectrum, with transmitted signals occupying a narrow frequency bandwidth.

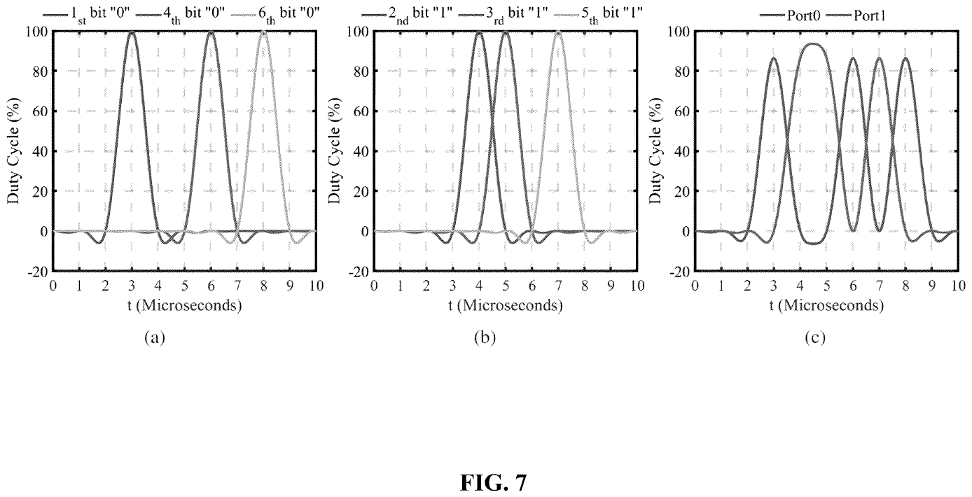

To mitigate spectrum expansion and avoid longer symbol durations, the proposed duty-cycle-modulated pulse shaping technique can be employed. The corresponding duty cycle for each port is shown in FIG. 7. FIG. 7 shows duty cycle of the duty-cycle-modulated pulse shaping, containing: part(a) Different symbols at port 0; part(b) Different symbols at port 1; and part(c) Overall duty cycle across both ports. The modulation period is significantly shorter than the symbol duration, allowing for 600 modulation periods of pulse signal for raised cosine modulation (α=0.8 and k=3). In other words, the original signal is extended into 6 μs and divided into 600 smaller periods, each modulation period assigned a varying duty cycle according to the raised cosine function, as shown in part(a) and part(b) of FIG. 7.

Each symbol time is also six times the original symbol time. However, within any single modulation period, the duty cycle for different ports can be realized by connecting the RF chain to port 0 for a specific duration and to port 1 for another duration as long as the total time does not exceed the modulation period. Thus, the transmission of different symbols with duty-cycle-modulated pulse shaping can be achieved simultaneously. As shown in part(c) of FIG. 7, this is the final duty cycle of the pulse signal for each port, achieved by overlapping different symbols in the time domain. It only requires one symbol duration for transmitting a single symbol. Although there are two symbol durations at the start and end of the transmission, their effect on transmission rate is negligible when transmitting long data sequences. It should also be noted that this is normalized so that the sum of the duty cycles for all ports does not exceed 100%.

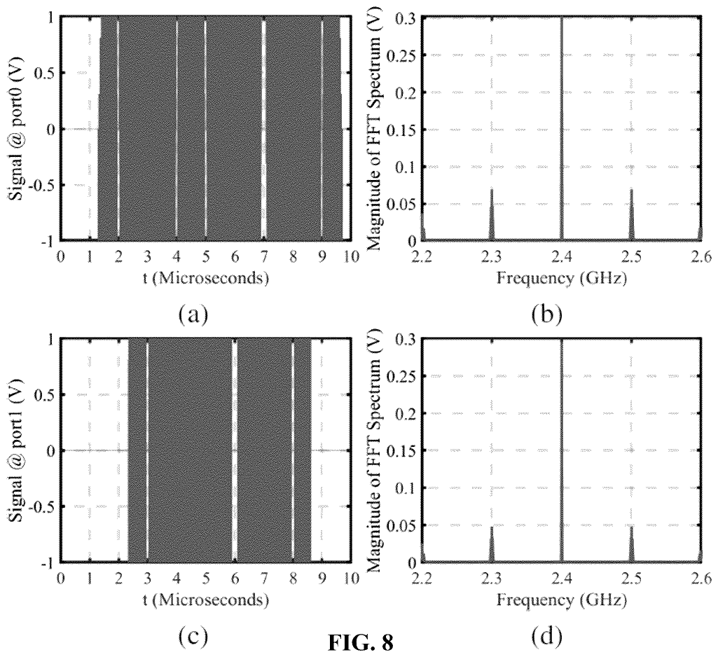

FIG. 8 shows signal with raised cosine (α=0.8 and k=3) duty-cycle-modulated pulse shaping for transmitting the bit sequence “0 1 1 0 1 0,” containing: part(a) Signals at port 0; part(b) Spectrum of signals at port 0; part(c) Signals at port 1; and part(d) Spectrum of signals at port 1. The transmitted signal in the time domain is shown in part(a) and part(c) of FIG. 8, while their spectrum is demonstrated in part(b) and part(d) of FIG. 8. The spectrum of the transmitted signal is clear and occupies a narrow bandwidth. There are also harmonics 100 MHz away from the signal of interest due to pulse modulation, which can be filtered by SAW filters. It should be noted that signals with duty-cycle-modulated pulse shaping may experience some loss due to these harmonics. However, as long as modulation occurs before the signal enters the power amplifier, the power loss can be ignored, and power efficiency will remain largely unaffected.

### The First Approach-Application Example II: IBFD System

Another promising application for the proposed duty-cycle-modulated pulse shaping technique is in in-band full-duplex (IBFD) systems. Traditional IBFD systems have been extensively researched, yet achieving the necessary high isolation-exceeding 80 dB-between the transmitter and receiver remains a significant challenge.

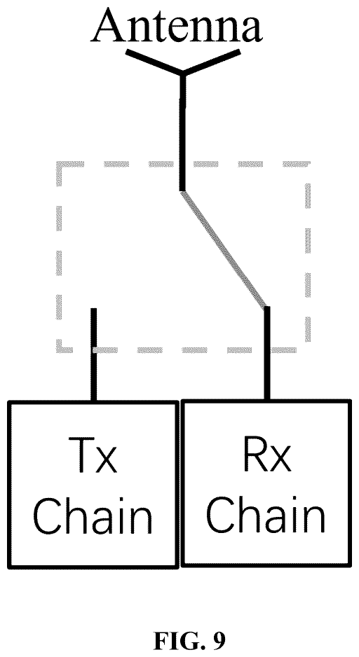

FIG. 9 shows a time-modulated in-band full-duplex (IBFD) system according to some embodiments of the present invention, in which, in a single symbol period, one half is allocated for transmission, while the other half is designated for reception.

An alternative approach to realizing an IBFD system involves utilizing time-division within each symbol duration to isolate transmission and reception in the time domain. Specifically, for each symbol period, a portion is allocated for transmission while the remaining portion is used for reception. This configuration enables both transmission and reception within any given symbol duration, thereby achieving fullduplex functionality.

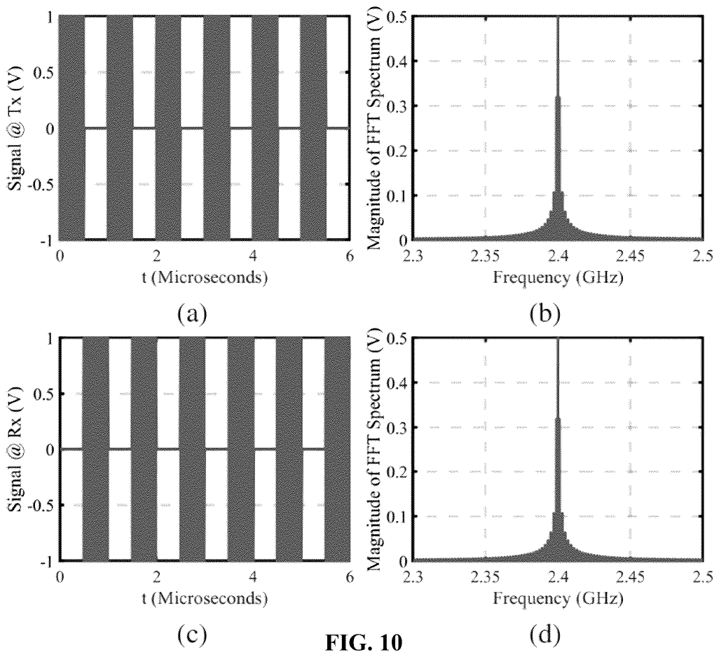

However, directly dividing transmission and reception within the symbol rate can lead to significant issues, such as spectrum expansion. To illustrate this, referred to as the example shown in FIG. 10, where the symbol duration is 1 ms.

FIG. 10 shows time division of transmission and reception in symbol rate, containing: part(a) Signals at the Tx; part(b) Spectrum of signals at the Tx; part(c) Signals at the Rx; and part(d) Spectrum of signals at the Rx. The first half of the duration is used for transmission, and the second half for reception. The carrier frequency is 2.4 GHz, and only a single frequency is considered. As depicted in part(b) and part(d) of FIG. 10, the spectra of both transmission and reception signals expand into a large bandwidth, resulting in undesired inter-channel interference.

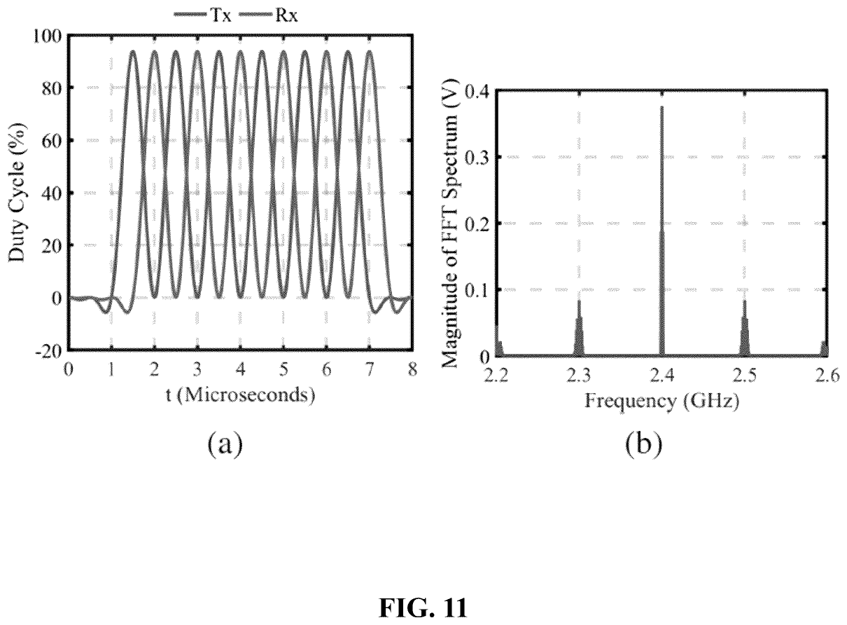

Similar to the SSK system, traditional pulse shaping could be employed, but this would significantly increase symbol duration and reduce system capacity. To address this issue, the proposed duty-cycle-modulated pulse shaping technique can be employed, as illustrated in FIG. 11.

FIG. 11 shows an IBFD system with the proposed duty-cycle-modulated pulse shaping technique, containing: part(a) Duty cycle at the Tx and Rx; and part(b) Spectrum of signals at both the Tx and Rx. In this approach, the original symbol duration is divided into numerous modulation periods. Each period is assigned a varying duty cycle according to the raised cosine (α=0.8 and k=3) function for both the transmitted and received signals of each symbol, as shown in part(a) of FIG. 11. This method results in a clear spectrum for both signals, occupying a narrow bandwidth. Additionally, harmonics that are 100 MHz away from the signal of interest, resulting from pulse modulation, can be effectively filtered out using SAW filters.

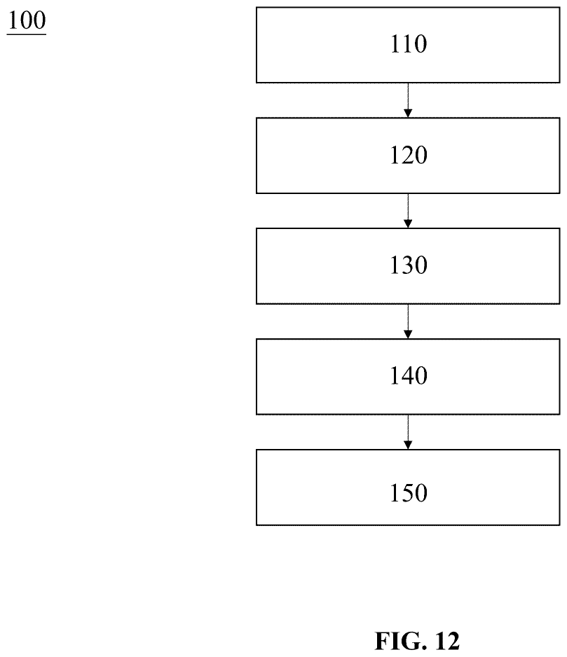

Based on the foregoing theoretical principles, the duty-cycle time-modulated waveform generation process can be implemented in a physical system configured to produce radio-frequency signals with controlled spectral characteristics. Through appropriate integration of switching elements, control logic, and waveform processing circuitry, the theoretical modulation mechanism described above can be realized as a concrete hardware and firmware architecture suitable for deployment in wireless communication devices. To illustrate such an implementation, a generalized waveform-generation system is described with reference to FIG. 12.

FIG. 12 illustrates a generalized waveform generation system 100 configured to implement duty-cycle-based time modulation according to some embodiments of the present invention. The waveform generation system 100 provides a structural framework for generating radio-frequency waveforms using the theoretical principles described above. The waveform generation system 100 may be implemented in hardware, firmware, or any combination thereof, and may interface with one or more radio-frequency front ends depending on deployment requirements. For example, the waveform generation system 100 includes a controller module 110, a duty-cycle modulation module 120, a waveform shaping module 130, a switching interface module 140, and an RF output module 150.

The controller module 110 is configured to generate timing control data corresponding to a sequence of modulation periods. The controller module 110 is further configured to determine a duty-cycle profile for each modulation period based on waveform parameters, symbol timing information, or externally supplied configuration data. The controller module 110 outputs the duty-cycle control data to downstream modules for signal generation.

The duty-cycle modulation module 120 is coupled to the controller module 110 and is configured to generate a periodic pulse signal for each modulation period according to the duty-cycle control data. The pulse signal includes ON intervals and OFF intervals whose relative durations correspond to the assigned duty cycle. The pulse signal may have a modulation frequency that is significantly higher than the symbol rate or waveform duration.

The waveform shaping module 130 is coupled to the duty-cycle modulation module 120 and is configured to apply the pulse signal to an input waveform to generate a time-modulated output waveform. The waveform shaping module 130 may multiply or otherwise combine the input waveform and the pulse signal such that the magnitude of the fundamental harmonic of the resulting waveform corresponds to the duty cycle of the pulse signal. The waveform shaping module 130 thereby produces an RF waveform shaped according to the duty-cycle profile determined by the controller module 110.

The switching interface module 140 is coupled downstream to the waveform shaping module 130 and upstream to the RF output module 150. The switching interface module 140 is configured to route the time-modulated waveform toward one or more output paths. The switching interface module 140 may control an RF switch, a multiport output structure, or other signal-routing circuitry to direct the waveform to a desired output. The operation of the switching interface module 140 may be synchronized with the modulation periods generated by the controller module 110.

The RF output module 150 is coupled to the switching interface module 140 and provides a physical interface to an external radio-frequency chain, antenna structure, or communication subsystem. The RF output module 150 receives the time-modulated waveform from the switching interface module 140 and outputs the waveform for transmission or further processing. The RF output module 150 may include filters, impedance matching components, amplification elements, or other circuitry depending on system requirements.

These modules shown in FIG. 12 represent a generalized architecture that may be extended or supplemented with application-specific elements depending on the deployment environment. Subsequent embodiments describe how the waveform generation system 100 may be integrated with additional modules to support port-based signaling mechanisms such as space shift keying, or to support time-division transmission and reception in in-band full-duplex systems. These embodiments build upon the core structure of the waveform generation system 100 while incorporating functional elements tailored to each application. Additional embodiments may incorporate other functional modules while relying on the core waveform generation functions of the waveform generation system 100.

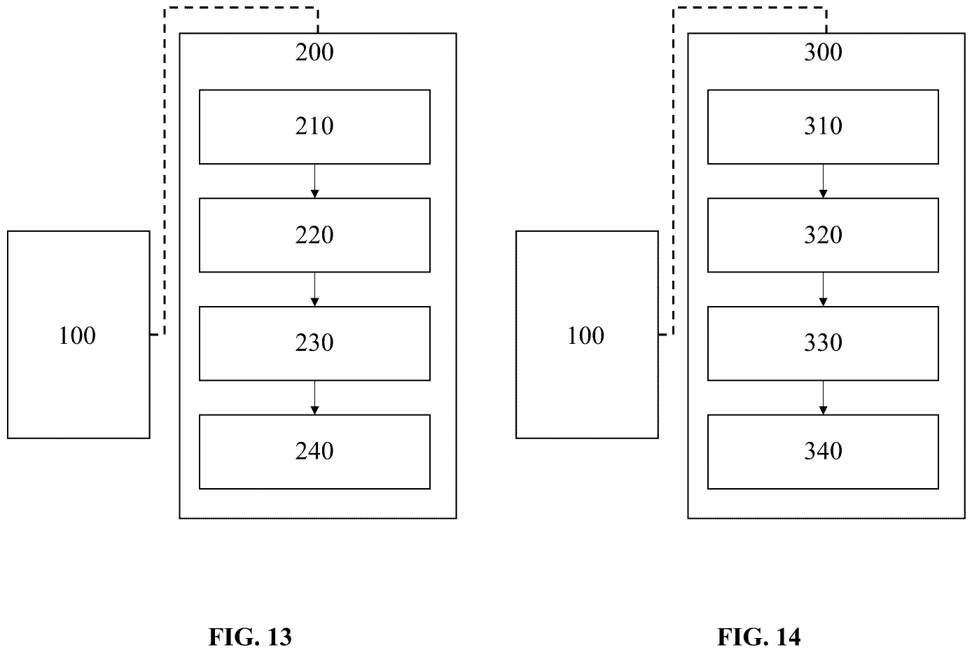

FIG. 13 illustrates an SSK extension system 200 configured to operate in conjunction with the waveform generation system 100 of FIG. 12 according to some embodiments of the present invention. The waveform generation system 100 generates a time-modulated waveform using duty-cycle-based time modulation and provides switching and RF output functions via the switching interface module 140 and the RF output module 150. The spatial modulation (SSK) extension system 200 cooperates with the waveform generation system 100 and with an SSK hardware topology such as that shown in FIG. 4 to support port-based signaling in a space shift keying transmitter. In some embodiments, the SSK extension system 200 includes a port selection module 210, a port-specific duty-cycle scheduling module 220, an SSK switching control module 230, and an RF port output module 240.

The port selection module 210 is configured to receive a bit sequence or symbol stream from a baseband processing unit or from the controller module 110 and to determine, for each symbol interval, which antenna port of the SSK structure shown in FIG. 4 is to be used for transmission. The port selection module 210 generates port assignment data indicating the selected port for each symbol. The port selection module 210 is coupled to the controller module 110 to receive symbol timing information so that the port assignment data is aligned with the modulation periods used by the waveform generation system 100.

The port-specific duty-cycle scheduling module 220 is coupled to the port selection module 210 and to the controller module 110. The port-specific duty-cycle scheduling module 220 is configured to generate, for each modulation period within a symbol interval, scheduling data that associates the duty-cycle profile of the time-modulated waveform with the selected antenna port. In some embodiments, the port-specific duty-cycle scheduling module 220 partitions the symbol-level duty-cycle information provided by the controller module 110 into per-port segments so that only the selected port is associated with a non-zero duty-cycle during each modulation period. The port-specific duty-cycle scheduling module 220 outputs scheduling data to the SSK switching control module 230.

The SSK switching control module 230 is coupled to the port-specific duty-cycle scheduling module 220 and to the switching interface module 140 of the waveform generation system 100. The SSK switching control module 230 is configured to generate switching control signals for the switching interface module 140 based on the scheduling data received from the module 220 and timing information received from the controller module 110. During each modulation period, the SSK switching control module 230 drives the switching interface module 140 so that the time-modulated waveform produced by the waveform shaping module 130 is routed toward the antenna port selected by the port selection module 210.

The RF port output module 240 is coupled between the RF output module 150 of the waveform generation system 100 and the multiport antenna structure of FIG. 4. The RF port output module 240 is configured to provide physical connectivity from the RF output module 150 to a plurality of antenna ports and to cooperate with the switching interface module 140 under the control of the SSK switching control module 230. In some embodiments, the RF port output module 240 includes matching networks, routing conductors, or additional filtering elements that guide the time-modulated waveform from the RF output module 150 to the selected antenna port while other ports remain non-radiating.

In SSK systems, the technique reconstructs a pulse-shaped envelope without requiring overlap between symbol intervals, permitting the original symbol rate to be maintained while adhering to the single-active-port constrain.

Through the interaction of the waveform generation system 100 and the SSK extension system 200, a duty-cycle-based time-modulated waveform generated by the controller module 110, the duty-cycle modulation module 120, and the waveform shaping module 130 is selectively routed by the switching interface module 140 and the RF port output module 240 to one antenna port at a time, as determined by the port selection module 210 and the port-specific duty-cycle scheduling module 220. The SSK extension system 200 therefore adapts the generalized waveform generation capabilities of the waveform generation system 100 to the port-based signaling constraints of an SSK transmitter while maintaining cooperative operation between the functional modules.

FIG. 14 illustrates an IBFD extension system 300 configured to operate in conjunction with the waveform generation system 100 of FIG. 12 according to some embodiments of the present invention. The waveform generation system 100 generates a time-modulated waveform using duty-cycle-based time modulation and provides switching and RF output functions via the switching interface module 140 and the RF output module 150. The in-band full-duplex (IBFD) extension system 300 cooperates with the waveform generation system 100 and with an IBFD hardware topology such as that shown in FIG. 9 to support time-division transmission and reception within a single symbol interval. In some embodiments, the IBFD extension system 300 includes a duplex timing module 310, a dual-path duty-cycle scheduling module 320, an IBFD switching control module 330, and a duplex RF routing module 340.

The duplex timing module 310 is configured to receive symbol timing information from the controller module 110 and to determine, for each symbol interval, the portions allocated for transmission and reception. The duplex timing module 310 generates timing boundary data identifying the start and end of the transmission interval and the reception interval. The duplex timing module 310 provides these timing boundaries to the dual-path duty-cycle scheduling module 320 and to the IBFD switching control module 330 so that both modules operate in alignment with the modulation periods generated by the waveform generation system 100.

The dual-path duty-cycle scheduling module 320 is coupled to the duplex timing module 310 and to the controller module 110. The dual-path duty-cycle scheduling module 320 is configured to generate separate duty-cycle profiles for the transmission interval and the reception interval within each symbol period. In some embodiments, the dual-path duty-cycle scheduling module 320 partitions the symbol-level duty-cycle information provided by the controller module 110 into two non-overlapping segments so that the transmission path is associated with the assigned duty-cycle values during the transmission interval, while the reception path is associated with the assigned duty-cycle values during the reception interval. The dual-path duty-cycle scheduling module 320 outputs the resulting scheduling data to the IBFD switching control module 330.

The IBFD switching control module 330 is coupled to the dual-path duty-cycle scheduling module 320, the duplex timing module 310, and the switching interface module 140 of the waveform generation system 100. The IBFD switching control module 330 is configured to generate switching control signals for the switching interface module 140 based on the scheduling data received from the module 320 and the timing boundaries received from the module 310. During each modulation period, the IBFD switching control module 330 directs the switching interface module 140 to route the time-modulated waveform toward the transmission path or the reception path depending on whether the current modulation period falls within the transmission interval or the reception interval.

The duplex RF routing module 340 is coupled between the RF output module 150 of the waveform generation system 100 and the IBFD antenna structure of FIG. 9. The duplex RF routing module 340 is configured to provide physical connectivity to both the transmission chain and the reception chain and to cooperate with the switching interface module 140 under the control of the IBFD switching control module 330. In some embodiments, the duplex RF routing module 340 includes matching networks, isolation circuits, or additional filtering elements that guide the time-modulated waveform toward the transmission circuitry during the transmission interval and allow the reception circuitry to receive incoming signals during the reception interval.

In IBFD systems, the duty-cycle-modulated shaping prevents spectrum expansion at the boundary between transmission and reception intervals, thereby enabling full-duplex signaling within a single symbol duration without introducing excessive out-of-band emissions.

Through the interaction of the waveform generation system 100 and the IBFD extension system 300, duty-cycle-based time modulation produced by the controller module 110, the duty-cycle modulation module 120, and the waveform shaping module 130 is selectively routed by the switching interface module 140 and the duplex RF routing module 340 to support transmission and reception within a single symbol interval. The timing boundaries generated by the duplex timing module 310 and the scheduling data produced by the dual-path duty-cycle scheduling module 320 ensure that the transmission and reception intervals do not overlap, thereby enabling in-band full-duplex functionality while adhering to symbol-duration constraints.

### The Second Approach: Duty-Cycle Time-Modulated Multicarrier Waveform Scheme

As shown by the analytical relationship of equation (4), the magnitude of the fundamental harmonic component of a pulse-modulated signal varies proportionally with the duty cycle of the applied pulse waveform. Building upon this principle, the proposed duty-cycle-modulated OFDM technique utilizes a pulse signal whose duty cycle continuously changes over time so that the resulting fundamental harmonic reproduces the instantaneous value of the composite OFDM time-domain waveform. Rather than shaping the envelope of a carrier in the conventional manner, the time-varying duty cycle itself encodes the multi-subcarrier superposition characteristic of OFDM. When the modulation period of the pulse signal is significantly shorter than the OFDM symbol duration, the reconstructed waveform exhibits behavior closely matching that of conventional OFDM. Furthermore, because the pulse waveform operates at a high modulation frequency, the unwanted harmonics produced by the switching action appear far from the band of interest, allowing them to be removed by standard RF filtering components.

For illustration, a port-based transmitter architecture such as the configuration previously shown in FIG. 4 may be employed as a platform to demonstrate the operation of the duty-cycle-modulated OFDM scheme. In this arrangement, symbol selection is implemented by activating one of the antenna ports during a given transmission interval while maintaining the power amplifier after the modulation stage so that modulation-induced spectral components do not substantially affect power efficiency. Although the same SSK hardware structure is used as in the pulse-shaping example, its purpose here is solely to provide a restricted signaling environment in which only one port may radiate at a time, thereby highlighting how the proposed technique synthesizes a multi-subcarrier waveform despite the port-selection constraint.

As an example, consider an OFDM signal comprising six subchannels, each having a 0.1-MHz bandwidth and center frequencies ranging from 2.4001 GHz to 2.4006 GHz. The OFDM symbol duration is assumed to be 10 microseconds. A pulse signal operating at a 100-MHz modulation frequency, corresponding to a 10-nanosecond modulation period, may be used to generate a sequence of duty cycles that track the instantaneous OFDM waveform amplitude. Under this configuration, each of the six subchannels carries one bit of the sequence “0 1 1 0 1 0” within the same OFDM symbol interval. Although the transmitter hardware allows activation of only a single port at any given moment, the continuous variation of the duty cycle enables the system to replicate the composite multi-subcarrier waveform over time, thereby approximating the behavior of conventional OFDM without violating the single-port constraint.

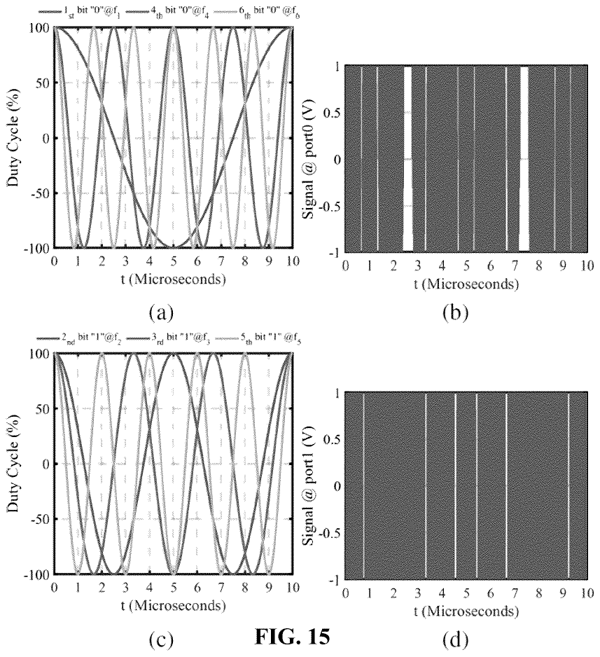

FIG. 15 shows a duty cycle and signals for transmitting the bit sequence “0 1 1 0 1 0” across six subchannels, containing: part(a) Duty cycle at Port 0; part(b) Signals at Port 0; part(c) Duty cycle at Port 1; and part(d) Signals at Port 1. Instead of applying traditional OFDM by modulating its envelope, a high-frequency pulse signal is utilized with a modulation period of 10 ns. Consequently, for the 10 μs duration of the signal, there are a total of 1000 modulation periods. For each modulation period, a different duty cycle is assigned to each subchannel and the appropriate port based on the bits to be transmitted, as shown in part(c) and part(d) of FIG. 15. The 1st, 4th, and 6th subchannels are implemented by varying the duty cycle through port 0 to transmit bit “0”, while the remaining three channels are implemented through port 1 to transmit bit “1.” The corresponding time-domain signal is depicted in part(b) and part(d) of FIG. 15, where it can be observed that while the duty cycle changes over time, the magnitude remains constant.

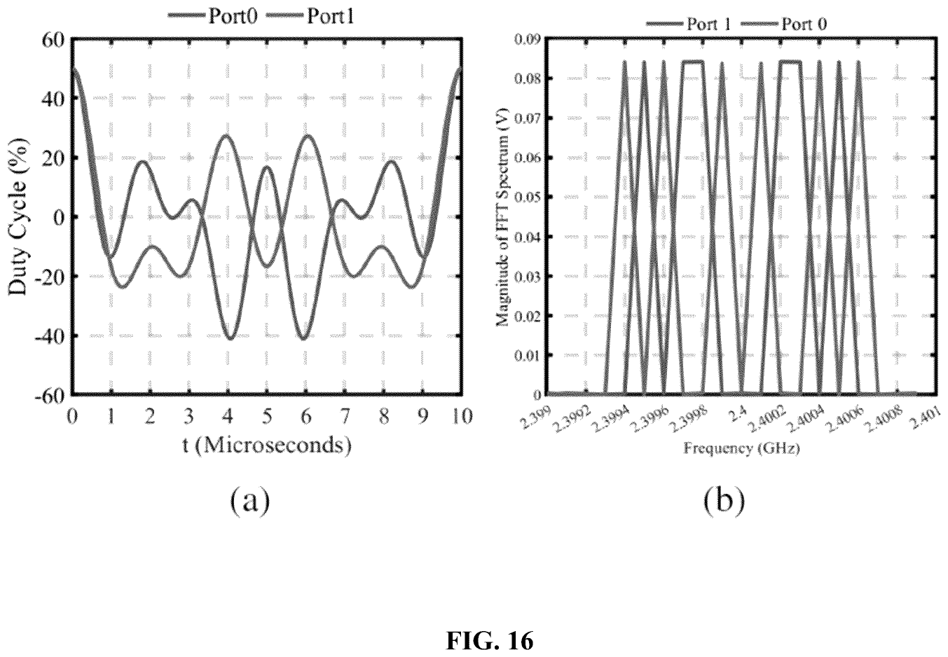

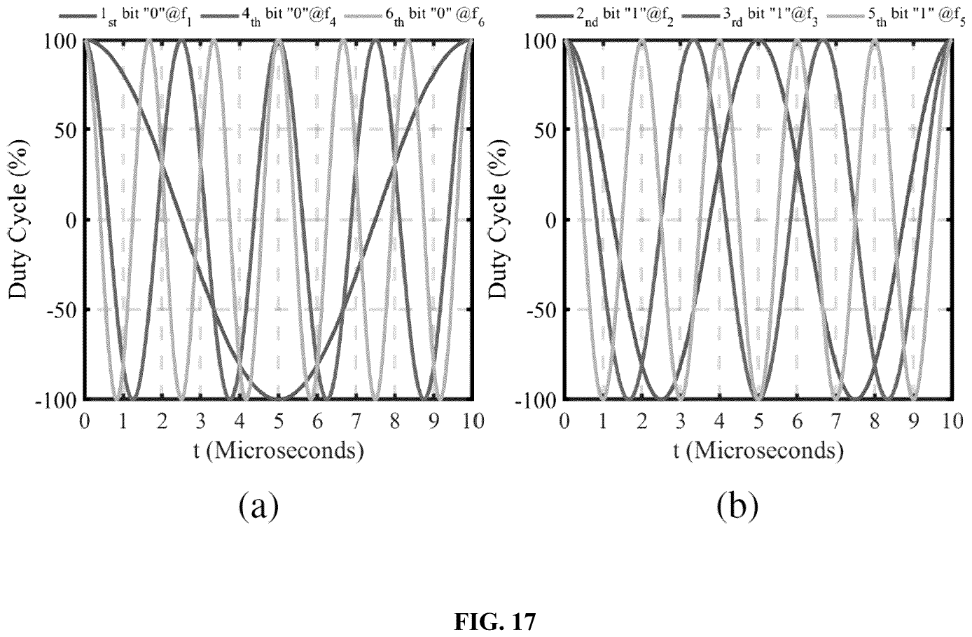

FIG. 16 shows the duty-cycle behavior and corresponding spectral characteristics for the duty-cycle-modulated OFDM example, containing: part(a) Overall duty cycle at both ports for transmitting the bit sequence “0 1 1 0 1 0”; and part(b) Spectrum of the signal transmitted through both ports. FIG. 17 shows duty-cycle characteristics for the duty-cycle-modulated OFDM example, containing: part(a) duty-cycle profiles of the individual subchannels; and part transmitting “1”; and part(b) duty-cycle profiles of the individual subchannels; and part transmitting “0”.

By summing the duty cycles across all subchannels and ports, the final duty cycle can be obtained, which is to be implemented for each modulation period, as shown in part(a) of FIG. 17. It should be noted that this is normalized so that the sum of the duty cycles for all ports does not exceed 100%, allowing them to be realized simultaneously in each modulation period. Part(b) of FIG. 17 illustrates the spectrum of the transmitted signal at both ports. As can be seen, port 0 contains frequency components in the channels of 2.4001, 2.4004, and 2.4006 GHz, while port 1 contains frequency components in the channels of 2.4002, 2.4003, and 2.4005 GHz, which align well with the bits transmitted. Moreover, the spectrum is free from multi-channel interference, and the two-sided spectrum results from using a cosine wave for modulation.

Another significant advantage of the proposed duty-cycle-modulated OFDM is the improved peak-to-average power ratio compared to traditional OFDM. This enhancement addresses a challenging issue related to the linearity of the power amplifier and the performance of the analog-to-digital converter.

The foregoing description of the duty-cycle-modulated OFDM technique has been presented using illustrative example(s) under specific signal conditions, such as real-valued subcarrier waveforms and particular bit-to-port mappings, for the purpose of clarity. However, the principles of duty-cycle-based time modulation disclosed herein are not limited to such illustrative conditions and may be extended to support more general OFDM waveforms, including complex-valued signals having sign, phase, and in-phase and quadrature (I/Q) components; for example, as employed in QPSK, QAM, or similar modulation formats.

In some embodiments, the sign or binary phase of a subcarrier waveform may be represented through complementary switching operations. For example, a first switching phase corresponding to a reference phase, such as 0 degrees, may be used to represent a positive amplitude or phase state, and a complementary switching phase, such as 180 degrees, may be used to represent a negative amplitude or inverted phase state. By selectively controlling the switching polarity associated with each modulation period, the duty-cycle-modulated waveform may encode both magnitude and sign information while preserving the fundamental harmonic relationship described above.

In some embodiments, phase information, including in-phase and quadrature components of a complex OFDM waveform, may be represented by introducing a controllable time delay within each modulation period, in addition to controlling the duty cycle. By adjusting the relative timing or onset position of the pulse signal within a modulation period, a corresponding phase shift may be imparted to the fundamental harmonic component of the time-modulated waveform. As such, both amplitude and phase of a composite OFDM waveform may be synthesized through a combination of duty-cycle control and timing offset control, enabling representation of general complex-valued OFDM signals without departing from the duty-cycle-based time-modulation framework.

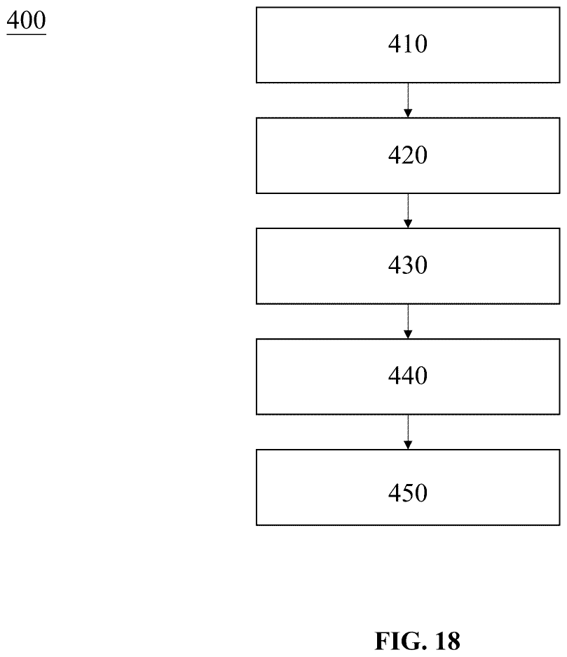

FIG. 18 illustrates a duty-cycle-modulated OFDM waveform generation system 400 configured to synthesize a multicarrier waveform using a time-varying duty-cycle sequence according to some embodiments of the present invention. The waveform generation system 400 provides a structural framework for converting OFDM symbol information into a corresponding duty-cycle representation and for producing a time-modulated RF waveform using the theoretical principles described earlier. The waveform generation system 400 may be implemented in hardware, firmware, or any combination thereof, and may interface with one or more radio-frequency front ends depending on deployment requirements. In some embodiments, the waveform generation system 400 includes an OFDM symbol controller 410, a duty-cycle encoding module 420, a composite duty-cycle generation module 430, an OFDM switching interface module 440, and an OFDM output module 450.

The OFDM symbol controller 410 is configured to receive OFDM symbol parameters such as subcarrier allocations, symbol duration, sampling intervals, and bit-to-subcarrier mappings. The OFDM symbol controller 410 further generates timing data associated with a sequence of modulation periods and provides subcarrier-level amplitude or symbol information to downstream modules for duty-cycle conversion.

The duty-cycle encoding module 420 is coupled to the OFDM symbol controller 410 and is configured to convert the instantaneous time-domain values of each subcarrier waveform into corresponding duty-cycle values. The duty-cycle encoding module 420 may compute, for each modulation period, a subcarrier-specific duty-cycle contribution based on the OFDM composite waveform.

The composite duty-cycle generation module 430 is coupled to the duty-cycle encoding module 420 and is configured to combine the duty-cycle contributions of all subcarriers into a normalized duty-cycle sequence. The composite duty-cycle generation module 430 assigns a final duty-cycle value to each modulation period such that the sum of all contributions does not exceed 100 percent, enabling physical implementation within each modulation period.

The OFDM switching interface module 440 is coupled downstream to the composite duty-cycle generation module 430 and is configured to apply the duty-cycle sequence to a high-frequency pulse-modulated waveform. The OFDM switching interface module 440 may operate a switching network or routing circuitry to generate a time-modulated RF waveform whose fundamental harmonic matches the composite OFDM waveform, including both amplitude and phase components of the multicarrier signal.

The OFDM output module 450 is coupled to the OFDM switching interface module 440 and provides a physical interface to an RF chain or antenna structure. The OFDM output module 450 outputs the synthesized OFDM waveform for transmission and may include filtering components to suppress harmonics introduced by the pulse-modulation operation.

The modules shown in FIG. 18 represent a generalized architecture that implements duty-cycle-modulated OFDM waveform synthesis. Although the system may be deployed in conjunction with port-based or switch-based transmission architectures such as those illustrated earlier (see FIG. 4), its operation does not depend on a specific hardware configuration. The waveform generation system 400 therefore provides a modular platform for duty-cycle-based OFDM realization under a variety of communication environments.

The waveform generation system 400 described above may be applied to communication architectures in which only a single RF chain or a single radiating port is available for transmission. In such systems, conventional OFDM cannot be directly implemented because multi-subcarrier synthesis normally requires the simultaneous generation of multiple sinusoidal components. By contrast, the duty-cycle-modulated OFDM technique implemented by system 400 produces a time-modulated waveform whose fundamental harmonic is equivalent to the composite OFDM signal, enabling multicarrier signaling without requiring multiple parallel oscillators or mixers. The generated waveform may therefore be transmitted through a single RF output path while maintaining spectral characteristics consistent with those of traditional OFDM.

The waveform generation system 400 may also be used in port-based or switch-based antenna architectures such as those in which only one antenna port may radiate at a time. In such configurations, multicarrier signaling is generally incompatible with the hardware constraint that prohibits simultaneous port activation. Because the duty-cycle-modulated OFDM waveform maintains a constant-amplitude structure and does not rely on envelope shaping, the system is able to synthesize the OFDM composite waveform within a single modulation path. The resulting waveform may then be routed through a selected antenna port using switching circuitry, allowing multiple subcarriers to be conveyed within each OFDM symbol while respecting single-port operation constraints.

### Explanation of Simultaneity:

For explanatory purposes, and without limiting the scope of the invention, in the present disclosure, the term “simultaneity” refers to the effective result observed over a symbol duration, rather than a physical instantaneous state. Since the modulation period (e.g., nanoseconds) is much shorter than the symbol duration (e.g., microseconds), the system can switch between different states or ports extremely fast. To a receiver or a baseband processor observing the signal over the full symbol duration, this rapid switching creates the effect that multiple signals or ports are active at the same time. Therefore, even though the RF switch physically connects to only one path at any split second, the rapid interleaving allows the system to achieve the performance of simultaneous transmission for applications like OFDM or pulse shaping.

Although FIG. 12 and FIG. 18 respectively illustrate duty-cycle-based pulse-shaping and duty-cycle-based OFDM waveform synthesis, both embodiments may be interpreted as specific operational modes of a unified waveform generation architecture. In its generalized form, the apparatus includes a controller configured to provide waveform-defining parameters, a duty-cycle generation module configured to compute a time-varying duty-cycle sequence from those parameters, a pulse-modulation module configured to apply the duty-cycle sequence to a high-frequency pulse waveform, and an output interface configured to deliver a corresponding time-modulated radio-frequency signal. These core functional elements are common to both embodiments, irrespective of the particular waveform being synthesized.

In this generalized architecture, the controller is configured to receive waveform parameters such as symbol timing, amplitude profiles, subcarrier assignments, or shaping-function values, and to supply those values to the duty-cycle generation module. The duty-cycle generation module is configured to translate the supplied waveform parameters into a sequence of duty-cycle values for a series of modulation periods. The pulse-modulation module is configured to operate at a modulation frequency significantly higher than the symbol duration and to embed the duty-cycle sequence into a pulse-modulated carrier. The output interface is configured to transmit, route, or otherwise deliver the resulting time-modulated waveform toward an RF chain, port-selection structure, or antenna subsystem. Together, these modules define the functional boundary of the generalized waveform generation apparatus.

When the waveform parameters supplied by the controller correspond to a pulse-shaping envelope such as a raised-cosine profile, the duty-cycle generation module produces a duty-cycle sequence that reconstructs the desired pulse-shaped magnitude behavior. Under this configuration, the apparatus operates in the manner shown in FIG. 12, where the duty-cycle sequence implements the shaping function without extending symbol duration, and the output interface routes the resulting shaped waveform for port-based or switch-based transmission. Thus, FIG. 12 represents one instantiation of the generalized architecture operating in a pulse-shaping mode.

When the waveform parameters supplied by the controller represent the time-domain composite of multiple OFDM subcarriers, the duty-cycle generation module produces a duty-cycle sequence whose fundamental harmonic follows the instantaneous value of the OFDM composite waveform. Under this configuration, the apparatus operates in the manner shown in FIG. 18, synthesizing an OFDM waveform through duty-cycle modulation rather than through simultaneous multi-tone generation. The output interface may then deliver the reconstructed OFDM waveform through a single RF chain or through a selected port of a port-based antenna structure. Thus, FIG. 18 represents a second instantiation of the same generalized architecture operating in an OFDM waveform-generation mode.

The present invention provides two complementary duty-cycle-based waveform generation schemes that extend the applicability of time-modulated RF signaling to a broad range of communication environments. The first scheme employs duty-cycle modulation to reconstruct pulse-shaped single-carrier waveforms without extending symbol duration, thereby achieving spectrum confinement in systems that prohibit overlapping signals. The second scheme applies a similar modulation principle to generate multicarrier OFDM waveforms using a single RF chain or port-based architecture, enabling OFDM transmission in hardware platforms that cannot synthesize multiple subcarriers simultaneously. Both approaches rely on a unified waveform generation architecture capable of translating waveform-defining parameters into a time-varying duty-cycle sequence. Together, these techniques demonstrate how duty-cycle-based modulation can serve as a versatile foundation for advanced waveform design under practical RF hardware constraints.

As demonstrated in the pulse-shaping embodiments, the duty-cycle-based approach successfully replicates traditional shaping functions such as the raised-cosine envelope while maintaining the original symbol duration. This capability enables clear spectral confinement without imposing timing overlap, allowing pulse-shaped transmission to coexist with architectures that restrict simultaneous port activation. The method further shifts harmonic components far from the spectrum of interest, permitting simple filtering and retaining overall power efficiency. These features make the duty-cycle-based pulse-shaping technique suitable for applications such as space shift keying and in-band full-duplex systems where conventional pulse shaping is impractical.

The duty-cycle-modulated OFDM technique provides a mechanism for synthesizing a multicarrier waveform through a single time-modulated signal whose fundamental harmonic matches the composite OFDM waveform. This process eliminates the need for multiple subcarrier oscillators or mixers, making OFDM feasible in single-port or switch-based antenna structures. The method also reduces the peak-to-average power ratio because the generated waveform maintains a substantially constant amplitude prior to amplification, improving power amplifier efficiency and reducing nonlinear distortion. The resulting spectral characteristics align with those of conventional OFDM while remaining compatible with hardware architectures that prohibit simultaneous multicarrier generation.

The functional units and modules of the apparatuses and methods in accordance with the embodiments disclosed herein may be implemented using computing devices, computer processors, or electronic circuitries including but not limited to application specific integrated circuits (ASIC), field programmable gate arrays (FPGA), microcontrollers, and other programmable logic devices configured or programmed according to the teachings of the present disclosure. Computer instructions or software codes running in the computing devices, computer processors, or programmable logic devices can readily be prepared by practitioners skilled in the software or electronic art based on the teachings of the present disclosure.

All or portions of the methods in accordance to the embodiments may be executed in one or more computing devices including server computers, personal computers, laptop computers, mobile computing devices such as smartphones and tablet computers.

The embodiments may include computer storage media, transient and non-transient memory devices having computer instructions or software codes stored therein, which can be used to program or configure the computing devices, computer processors, or electronic circuitries to perform any of the processes of the present invention. The storage media, transient and non-transient memory devices can include, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

Each of the functional units and modules in accordance with various embodiments also may be implemented in distributed computing environments and/or Cloud computing environments, wherein the whole or portions of machine instructions are executed in distributed fashion by one or more processing devices interconnected by a communication network, such as an intranet, Wide Area Network (WAN), Local Area Network (LAN), the Internet, and other forms of data transmission medium.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

What is claimed is:

1. A waveform generation apparatus configured to generate a radio-frequency waveform using duty-cycle-based time modulation, comprising:
a controller module configured to provide waveform-defining parameters and timing information associated with a sequence of modulation periods;
a duty-cycle generation module coupled to the controller module and configured to generate, for each modulation period, a duty-cycle value based on the waveform-defining parameters;
a pulse-modulation module coupled to the duty-cycle generation module and configured to apply the duty-cycle value to a high-frequency pulse signal to produce a time-modulated waveform; and
an output interface module configured to deliver the time-modulated waveform toward a radio-frequency transmission path.

2. The waveform generation apparatus of claim 1, wherein the waveform-defining parameters correspond to a pulse-shaping envelope applied to a single-carrier waveform.

3. The waveform generation apparatus of claim 2, wherein the pulse-shaping envelope comprises a raised-cosine function having a roll-off factor and shaping length.

4. The waveform generation apparatus of claim 2, wherein the duty-cycle generation module is configured to generate duty-cycle values that reproduce the pulse-shaping envelope without extending a symbol duration.

5. The waveform generation apparatus of claim 1, further comprising a switching interface module configured to route the time-modulated waveform through one of a plurality of antenna ports.

6. The waveform generation apparatus of claim 5, wherein only one antenna port is permitted to radiate at any given time instant.

7. The waveform generation apparatus of claim 6, wherein the switching interface module is configured to assign different duty-cycle portions of each modulation period to different antenna ports based on a port-selection symbol.

8. The waveform generation apparatus of claim 7, wherein the duty-cycle values form a sequence that corresponds to pulse-shaped symbols transmitted through one of the antenna ports without overlapping time-domain envelopes.

9. The waveform generation apparatus of claim 1, wherein a symbol duration is partitioned into a transmission duration and a reception duration.

10. The waveform generation apparatus of claim 9, wherein the duty-cycle generation module is configured to generate separate duty-cycle sequences for the transmission duration and the reception duration.

11. The waveform generation apparatus of claim 10, wherein the time-modulated waveform generated by the pulse-modulation module has reduced spectral expansion at a boundary between the transmission duration and the reception duration.

12. The waveform generation apparatus of claim 1, wherein the waveform-defining parameters correspond to time-domain values of a composite orthogonal frequency-division multiplexing waveform.

13. The waveform generation apparatus of claim 12, wherein the controller module is configured to provide subcarrier allocations, symbol duration, and bit-to-subcarrier mappings.

14. The waveform generation apparatus of claim 12, wherein the duty-cycle generation module computes a duty-cycle contribution for each of a plurality of subcarriers during each modulation period.

15. The waveform generation apparatus of claim 12, wherein the apparatus synthesizes the composite OFDM waveform using a single radio-frequency chain.

16. The waveform generation apparatus of claim 12, further comprising a port-selection structure configured to map subsets of subcarriers of the composite OFDM waveform to respective antenna ports.

17. A method for generating a radio-frequency waveform using duty-cycle-based time modulation, comprising:
receiving waveform-defining parameters and timing information for a sequence of modulation periods;
generating, for each modulation period, a duty-cycle value based on the waveform-defining parameters;
applying the duty-cycle value to a pulse signal having a modulation frequency higher than a symbol rate of the radio-frequency waveform to produce a time-modulated waveform, wherein a fundamental harmonic of the time-modulated waveform corresponds to the waveform-defining parameters; and
outputting the time-modulated waveform toward a radio-frequency transmission path.

18. The method of claim 17, wherein the waveform-defining parameters correspond to a pulse-shaping envelope, and generating the duty-cycle value comprises generating duty-cycle values that reproduce the pulse-shaping envelope without extending a symbol duration.

19. The method of claim 17, further comprising: partitioning a symbol duration into a transmission duration and a reception duration, and generating separate duty-cycle sequences for the transmission duration and the reception duration.

20. The method of claim 17, wherein the waveform-defining parameters correspond to time-domain values of a composite orthogonal frequency-division multiplexing waveform, and generating the duty-cycle value comprises computing duty-cycle contributions for a plurality of subcarriers during each modulation period.
